(19) United States
(12) Patent Application Publication
(10) Pub. No.: US 2026/0358728 A1
(43) Pub. Date: Nov. 12, 2026

(54) PELLICLE MEMBRANE TRANSFERRING SYSTEM AND METHOD THEREOF

(71) Applicant: TAIWAN SEMICONDUCTOR MANUFACTURING COMPANY, LTD., Hsinchu (TW)

(72) Inventors: Yen-Chi CHEN, Tainan City (TW); Yen-Hsiang CHEN, Tainan City (TW); Yu-Chen YANG, Hsinchu City (TW); Chia-Tung KUO, Hsinchu City (TW); Wei-Hao LEE, Taipei City (TW); Huan-Ling LEE, Hsinchu County (TW)

(73) Assignee: TAIWAN SEMICONDUCTOR MANUFACTURING COMPANY, LTD., Hsinchu (TW)

(21) Appl. No.: 19/200,249

(22) Filed: May 6, 2025

(51) Int. Cl. G03F 7/00; G03F 1/62; H10P 72/10

(52) U.S. Cl. CPC G03F 7/70733; G03F 1/62; H10P 72/1906

(57) ABSTRACT

A method includes placing a pellicle border on a lifting stage, wherein the lifting stage comprises at least one force sensor; lifting the lifting stage to move the pellicle border toward to contact a pellicle membrane, wherein during lifting the lifting stage, the at least one force sensor in the lifting stage detects a force exerted on the lifting stage; and stopping moving the pellicle border once the force detected by the at least one force sensor reaches a predetermined value.

### BACKGROUND

The semiconductor integrated circuit (IC) industry has experienced rapid growth. Technological advances in IC materials and design have produced generations of ICs where each generation has smaller and more complex circuits than the previous generation. However, these advances have increased the complexity of processing and manufacturing ICs and, for these advances to be realized, similar developments in IC processing and manufacturing are needed. In the course of integrated circuit evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system according to some embodiments of the present disclosure.

FIG. 2 is a schematic view of a EUV mask according to some embodiments of the present disclosure.

FIGS. 3A and 3B are a schematic view and a cross-sectional view of a pellicle structure in accordance with some embodiments.

FIGS. 4A to 5C illustrate various stages of transferring a pellicle membrane on a pellicle border in accordance with some embodiments.

FIG. 6 is a method of operating a pellicle membrane transferring system in accordance with some embodiments.

FIGS. 7A and 7B are a schematic view and a cross-sectional view of a pellicle structure in accordance with some embodiments.

FIGS. 8A to 8C are different conditions during transferring a pellicle membrane on a pellicle border in accordance with some embodiments.

FIG. 8D is a displacement versus force plot in accordance with some embodiments.

FIGS. 9A to 9B illustrate various stages of transferring a pellicle membrane on a pellicle border in accordance with some embodiments.

FIGS. 10A and 10B are a schematic view and a cross-sectional view of a pellicle membrane transferring system in accordance with some embodiments.

FIG. 11 is a top view of a pellicle border in accordance with some embodiments.

FIG. 12 is a schematic view of a pellicle membrane transferring system in accordance with some embodiments.

FIGS. 13A and 13B are a schematic view and a cross-sectional view of a pellicle membrane transferring system in accordance with some embodiments.

FIGS. 14A and 14B are a schematic view and a cross-sectional view of a pellicle membrane transferring system in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits. One of ordinary skill in the art will appreciate that the dimensions may be varied according to different technology nodes. One of ordinary skill in the art will recognize that the dimensions depend upon the specific device type, technology generation, minimum feature size, and the like. It is intended, therefore, that the term be interpreted in light of the technology being evaluated.

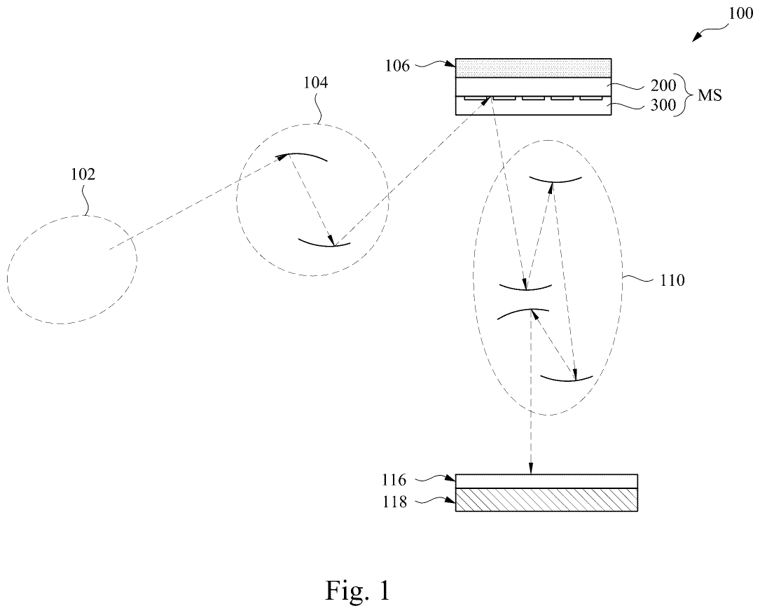

FIG. 1 is a schematic view of a lithography system according to some embodiments of the present disclosure. Shown there is a schematic view of a lithography system 100. The lithography system 100 may also be generically referred to as a scanner that is operable to perform lithographic processes including exposure with a respective radiation source and in a particular exposure mode. In at least some of the present embodiments, the lithography system 100 includes an extreme ultraviolet (EUV) lithography system designed to expose a resist layer by EUV light. Inasmuch, in various embodiments, the resist layer includes a material sensitive to the EUV light (e.g., an EUV resist). The lithography system 100 includes a plurality of subsystems such as a radiation source 102, an illuminator 104, a mask stage 106 configured to receive a mask 200, a pellicle structure 300, projection optics 110, and a substrate stage 118 configured to receive a semiconductor substrate 116.

In the embodiments described herein, the radiation source 102 may be used to generate the EUV light. In some embodiments, the radiation source 102 includes a plasma source, such as for example, a discharge produced plasma (DPP) or a laser produced plasma (LPP). In some examples, the EUV light may include light having a wavelength ranging from about 1 nm to about 100 nm. In one particular example, the radiation source 102 generates EUV light with a wavelength centered at about 13.5 nm. Accordingly, the radiation source 102 may also be referred to as an EUV radiation source 102. In some embodiments, the radiation source 102 also includes a collector, which may be used to collect EUV light generated from the plasma source and to direct the EUV light toward imaging optics such as the illuminator 104.

As described above, light from the radiation source 102 is directed toward the illuminator 104. In some embodiments, the illuminator 104 may include reflective optics (e.g., for the EUV lithography system 100), such as a single mirror or a mirror system having multiple mirrors in order to direct light from the radiation source 102 onto the mask stage 106, and particularly to the mask 200 secured on the mask stage 106. In some examples, the illuminator 104 may include a zone plate, for example, to improve focus of the EUV light. In some embodiments, the illuminator 104 may be configured to shape the EUV light passing therethrough in accordance with a particular pupil shape, and including for example, a dipole shape, a quadrapole shape, an annular shape, a single beam shape, a multiple beam shape, and/or a combination thereof. In some embodiments, the illuminator 104 is operable to configure the mirrors (i.e., of the illuminator 104) to provide a desired illumination to the mask 200. In one example, the mirrors of the illuminator 104 are configurable to reflect EUV light to different illumination positions. In some embodiments, a stage prior to the illuminator 104 may additionally include other configurable mirrors that may be used to direct the EUV light to different illumination positions within the mirrors of the illuminator 104. In some embodiments, the illuminator 104 is configured to provide an on-axis illumination (ONI) to the mask 200. In some embodiments, the illuminator 104 is configured to provide an off-axis illumination (OAI) to the mask 200. It should be noted that the optics employed in the EUV lithography system 100, and in particular optics used for the illuminator 104 and the projection optics 110, may include mirrors having multilayer thin-film coatings known as Bragg reflectors. By way of example, such a multilayer thin-film coating may include alternating layers of Mo and Si, which provides for high reflectivity at EUV wavelengths (e.g., about 13 nm).

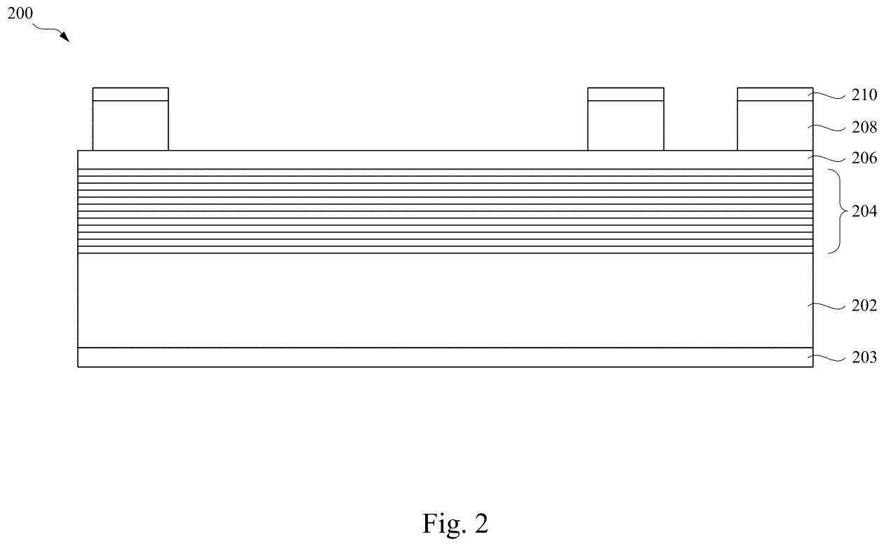

As discussed above, the lithography system 100 also includes the mask stage 106 configured to secure the mask 200. Since the lithography system 100 may be housed in, and thus operate within, a high-vacuum environment, the mask stage 106 may include an electrostatic chuck (e-chuck) to secure the mask 200. As with the optics of the EUV lithography system 100, the mask 200 is also reflective. Details of the mask 200 will be discussed in more detail below with reference to the example of FIG. 2.

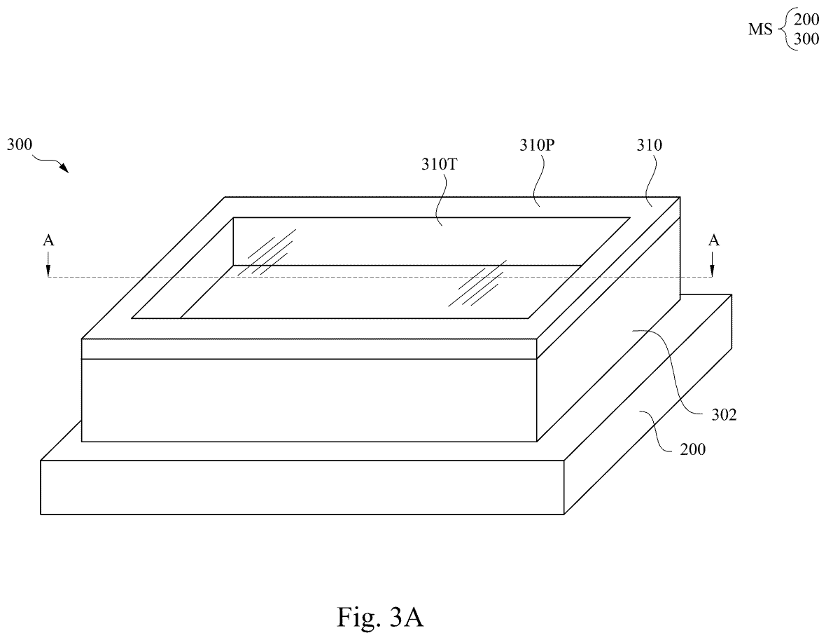

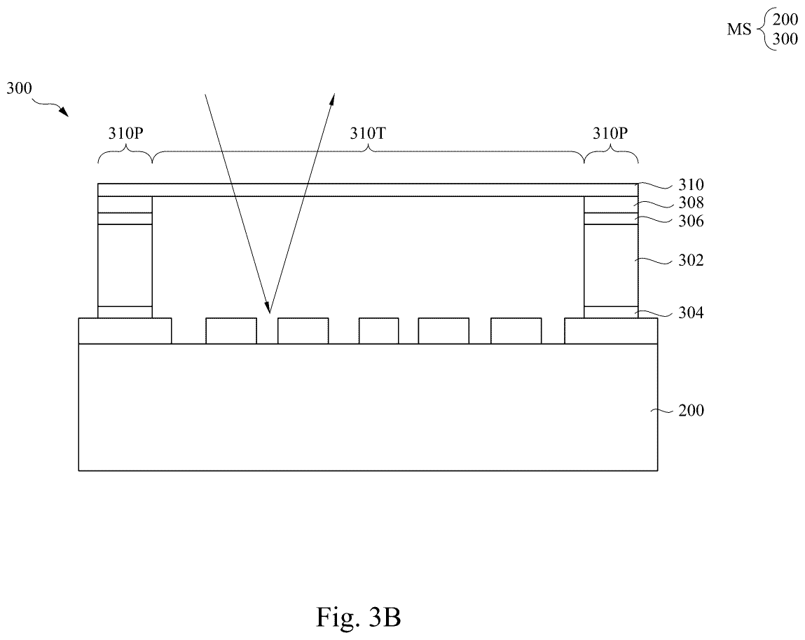

The pellicle structure 300 is positioned over the mask 200. In some embodiments, the pellicle structure 300 protects the mask 200 from particles and keeps the particles out of focus so that they do not produce an image, which may cause defects during the lithography process. Details of the pellicle structure 300 will be discussed in more detail below with reference to the example of FIGS. 3A and 3B. In some embodiments, the pellicle structure 300 and the mask 200 may collectively referred to a mask system MS.

As illustrated in the example of FIG. 1, light passes through the pellicle structure 300, the mask 200 reflects the light, and the reflected light passes through the pellicle structure 300 again and is directed toward the projection optics 110, which collects the EUV light reflected from the mask 200. By way of example, the EUV light collected by the projection optics 110 (reflected from the mask 200) carries an image of the pattern defined by the mask 200. In various embodiments, the projection optics 110 provides for imaging the pattern of the mask 200 onto the semiconductor substrate 116 secured on the substrate stage 118 of the lithography system 100. In particular, in various embodiments, the projection optics 110 focuses the collected EUV light and projects the EUV light onto the semiconductor substrate 116 to expose an EUV resist layer deposited on the semiconductor substrate 116. As described above, the projection optics 110 may include reflective optics, as used in EUV lithography systems such as the lithography system 100. In some embodiments, the illuminator 104 and the projection optics 110 are collectively referred to as an optical module of the lithography system 100.

As discussed above, the lithography system 100 also includes the substrate stage 118 to secure the semiconductor substrate 116 to be patterned. In various embodiments, the semiconductor substrate 116 includes a semiconductor wafer, such as a silicon wafer, germanium wafer, silicon-germanium wafer, III-V wafer, or other type of wafer as known in the art. The semiconductor substrate 116 may be coated with a resist layer (e.g., an EUV resist layer) sensitive to EUV light. In the embodiments described herein, the various subsystems of the lithography system 100, including those described above, are integrated and are operable to perform lithography exposing processes including EUV lithography processes. It is understood that the lithography system 100 may further include other modules or subsystems which may be integrated with (or be coupled to) one or more of the subsystems or components described herein.

In some embodiments, various device elements may be formed over the semiconductor substrate 116. Examples of the various device elements include transistors (e.g., metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.), diodes, or other suitable elements. Various processes may be used to form the various device elements, including deposition, etching, implantation, photolithography, annealing, and/or other applicable processes.

The lithography system 100 also includes a light distribution detector and a light distribution detector configured to detect light distributions at different position of the lithography system 100. In greater detail, the light distribution detectoris positioned along an optical path from the radiation source 102 and the mask system MS, so as to detect a light distribution projected onto the mask system MS. On the other hand, the light distribution detector is positioned along an optical path from the mask system MS to the semiconductor substrate 116, so as to detect a light distribution reflected from the mask system MS.

FIG. 2 is a schematic view of a EUV mask according to some embodiments of the present disclosure. In greater detail, FIG. 2 illustrates an example cross-section of the EUV mask 200 of FIG. 1. The EUV mask 200 may include a substrate 202 having a backside coating layer 203, a multi-layer structure 204, a capping layer 206, and one or more absorbers 208 having an anti-reflective coating (ARC) layer 210. The absorbers 208 may collectively form a patterned image, which will be transferred onto a semiconductor wafer (e.g., the semiconductor substrate 116) by the lithography system 100. In some embodiments, the substrate 202 includes a low thermal expansion material (LTEM) substrate (e.g., such as TiO₂ doped SiO₂), and the backside coating layer 203 includes a chromium nitride (CrₓN_{y}) layer. By way of example, the multi-layer structure 204 may include molybdenum-silicon (Mo-Si) multi-layers deposited on top of the substrate 202 for example, using an ion deposition technique. In some embodiments, the multi-layer structure 204 has a thickness of about 250-350 nm, and in some examples each Mo-Si layer pair has a thickness of about 3 nm (for the Mo layer) and about 4 nm (for the Si layer). In various embodiments, the capping layer 206 includes a ruthenium (Ru) capping layer. In other embodiments, the capping layer 206 may include a Si capping layer. The capping layer 206 may help to protect the multi-layer structure 204 (e.g., during fabrication of the mask 200) and may also serve as an etch-stop layer for a subsequent absorber layer etch process. In some embodiments, the absorbers 208 may include for example, a TaₓN_{y} layer or a TaₓB_{y}O_{z}Nᵤ layer, and are configured to absorb EUV light. In some examples, other materials may be used for the absorbers 208, such as Al, Cr, Ta, and W, among others. In some examples, the ARC layer 210 includes at least one of a TaₓB_{y}O_{z}Bᵤ layer, a HfₓOy layer, or a SiₓO_{y}N_{z} layer. While some examples of materials that may be used for each of the substrate 202, the backside coating layer 203, the multi-layer structure 204, the capping layer 206, the absorbers 208, and the ARC layer 210 have been given, it will be understood that other suitable materials as known in the art may be equally used without departing from the scope of the present disclosure.

As described above, the mask 200 includes a patterned image defined by the absorbers 208, and the mask 200 may be used to transfer the patterned image (e.g., circuit and/or device patterns) onto a semiconductor wafer. To achieve a high fidelity pattern transfer from the patterned mask 200 to the semiconductor substrate 116, the lithography process should be defect free. As shown in FIG. 2, particles may be unintentionally deposited on the surface of the capping layer 206 and can result in degradation of lithographically transferred patterns if not removed. Particles may be introduced by any of a variety of methods such as during an etching process, a cleaning process, and/or during handling of the EUV mask 200. Accordingly, the mask 200 may be protected by a pellicle structure (e.g., the pellicle structure 300 of FIG. 1).

FIGS. 3A and 3B are a schematic view and a cross-sectional view of a pellicle structure in accordance with some embodiments, in which FIG. 3B is a cross-sectional view along line A-A of FIG. 3A. FIGS. 3A and 3B illustrate an example of the pellicle structure 300 of FIG. 1. Also shown in FIGS. 3A and 3B, the pellicle structure 300 is mounted over the mask 200. As discussed above, the mask 200 may include a patterned image used to pattern a semiconductor substrate by a lithographic process. In the present embodiments, the mask 200 is secured on a mask stage (e.g., the mask stage 106 of FIG. 1) collectively with the pellicle structure 300 during a lithography patterning process.

The pellicle structure 300 includes a pellicle frame 302 positioned over the mask 200. In some embodiments, the pellicle frame 302 is made of ceramic material, metal material, glass-ceramic material, graphite, another suitable material, or a combination thereof. In some embodiments, suitable process for forming the pellicle frame 302 includes machining process, injunction molding process, sintering process, photochemical etching process, another applicable process, or a combination thereof.

As shown in FIG. 3B, the pellicle structure 300 further includes a pellicle frame adhesive 304 between the pellicle frame 302 and the mask 200. In some embodiments, the pellicle frame adhesive 304 is made of crosslink type adhesive, thermoplastic elastomer type adhesive, polystyrene type adhesive, acrylic type adhesive, epoxy type adhesive, or a combination thereof. In some embodiments, a surface treatment may be performed on the pellicle frame 302 to enhance the adhesive property of the pellicle frame 302 to the pellicle frame adhesive 304. In some embodiments, the surface treatment includes an oxygen plasma treatment, another applicable treatment, or a combination thereof. However, the embodiments of the present disclosure are not limited thereto. In some other embodiments, no surface treatment is performed on the pellicle frame 302.

The pellicle structure 300 further includes a pellicle frame adhesive 306 over the pellicle frame 302. In some embodiments, the a pellicle frame adhesive 306 is made of thermoplastic elastomer type adhesive, acrylic type adhesive, epoxy type adhesive, polystyrene type adhesive, another suitable material, or a combination thereof.

The pellicle structure 300 further includes a pellicle border 308 positioned over the pellicle frame 302 through the pellicle frame adhesive 306. In some embodiments, the pellicle border 308 is made of ceramic material, metal material, glass-ceramic material, another suitable material, or a combination thereof. In some embodiments, suitable process for forming the pellicle border 308 includes machining process, injunction molding process, sintering process, photochemical etching process, another applicable process, or a combination thereof.

The pellicle structure 300 further includes a pellicle membrane 310 attached to the pellicle border 308. In some embodiments, the pellicle membrane 310 includes a peripheral portion 310P over the attached to the pellicle border and a light transmission portion 310T surrounded by the peripheral portion 310P. In some embodiments, the pellicle membrane 310 is attached to pellicle border 308 via van der Waals forces.

As described above, one or more layers of the pellicle membrane 310 are formed from nanotubes. In some embodiments, the nanotubes can be carbon nanotubes (CNTs) or boron nitride nanotubes (BNNTs) or silicon carbide nanotubes (SiCNTs) or molybdenum disulfide nanotubes (MoS₂NTs) or molybdenum diselenide (MoSe₂NTs) or tungsten disulfide nanotubes (WS₂NTs) or tungsten diselenide nanotubes (WSe₂NTs). In some embodiments, the nanotubes can be single-wall nanotubes or multi-wall nanotubes. It is possible for multi-wall nanotubes to be made of different materials, for example a CNT inside a BNNT, or vice versa. In some embodiments, the nanotubes can be metallic or semiconducting or electrically insulating. In some embodiments, dielectric layer and/or metal coating layer may be formed on the CNTs or inside the CNTs.

In addition, in some embodiments, one or more layers of the pellicle membrane 310 are formed from graphene or graphite. Such layers can provide more stiffness compared to layers formed from nanotubes. Graphite is made up of stacked graphene layers, and thus should be considered equivalent to graphene in this disclosure.

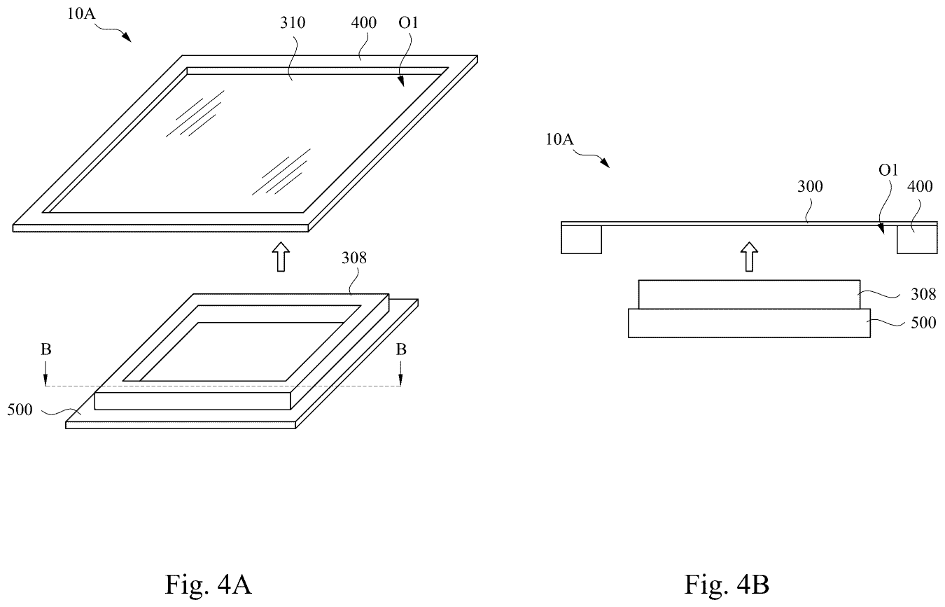

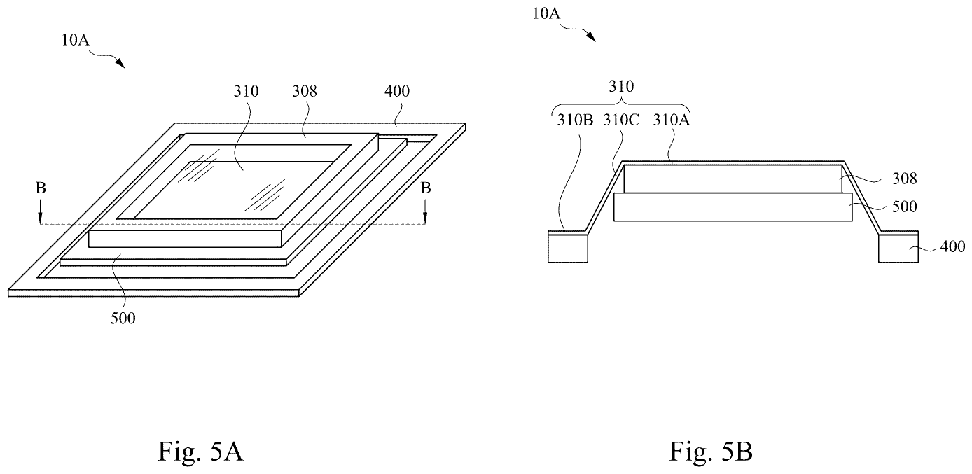

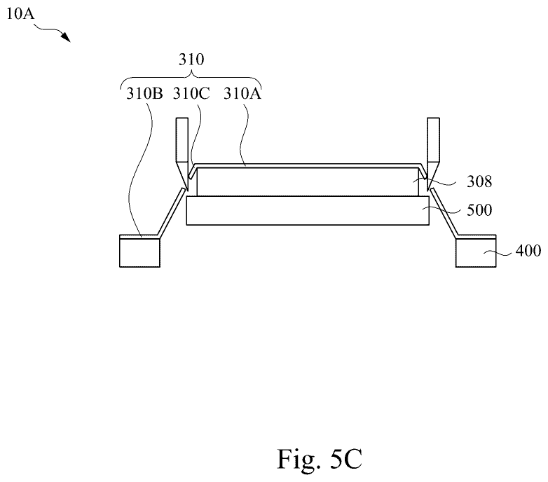

FIGS. 4A to 5C illustrate various stages of transferring a pellicle membrane on a pellicle border in accordance with some embodiments. In greater detail, FIGS. 4A to 5C describe an exemplary process of transferring the pellicle membrane 310 of FIGS. 3A and 3B on the pellicle border 308 of FIGS. 3A and 3B.

Reference is made to FIGS. 4A and 4B, in which FIG. 4B is a cross-sectional view along line B-B of FIG. 4A. Shown there is a pellicle membrane transferring system 10A, which includes a lifting stage 500 and a supporting frame 400 above the lifting stage 500. A pellicle membrane 310 is attached to a supporting frame 400. In some embodiments, the supporting frame 400 includes an opening O1, and thus a portion of bottom surface of the pellicle membrane 310 may be exposed through the opening O1 of the supporting frame 400 (see FIG. 4B). On the other hand, a pellicle border 308 is disposed on a lifting stage 500. In some embodiments, the lifting stage 500 is movable and is above to move the pellicle border 308 up and down along the vertical direction. In some embodiments, the dimension of the opening O1 of the supporting frame 400 is larger than the dimension of the pellicle border 308, such that the pellicle border 308 is able to pass through the opening O1 of the supporting frame 400.

Reference is made to FIGS. 5A and 5B, in which FIG. 5B is a cross-sectional view along line B-B of FIG. 5A. A pellicle membrane 310 is going to be transferred on the pellicle border 308. During the transferring process, the lifting stage 500 is moved upwards along the vertical direction (e.g., Z-direction), so as to push the pellicle border 308 toward the pellicle membrane 310 through the opening O1 of the supporting frame 400. As the lifting stage 500 continuously moved upwards, the top surface of the pellicle border 308 may touch the bottom surface of the pellicle membrane 310, and the pellicle membrane 310 is affixed to the pellicle border 308, for example via van der Waals forces. In some embodiments, the upward force may impart tensile in the pellicle membrane 310, and thus the pellicle membrane 310 may be stretched and may become thinner, smoother, and/or flatter, which will improve the transparency of the pellicle membrane 310.

As shown in FIG. 5B, in some embodiments, the pellicle membrane 310 may include a main portion 310A attached to the pellicle border 308, a fixing portion 310B attached to the supporting frame 400, and a connection portion 310C connecting the main portion 310A and the fixing portion 310B.

Reference is made to FIG. 5C. Once the pellicle border 308 is moved to a desired position, the pellicle membrane 310 is cut out at the connection portion 310C of the pellicle membrane 310, such that the main portion 310A of the pellicle membrane 310 attached to the pellicle border 308 is separated from other portions of the pellicle membrane 310. In some embodiments, the method of cutting is not limited, any suitable cutting method can be employed.

Afterwards, the pellicle border 308 and the pellicle membrane 310 attached to the pellicle border 308 can be removed from the lifting stage 500. Then, the pellicle border 308 can be mounted on a pellicle frame 302 through a pellicle frame adhesive 306 (see FIGS. 3A and 3B), and thus the pellicle structure 300 as discussed in FIGS. 3A and 3B is formed.

As mentioned above, during the vertical movement of the pellicle border 308, the upward force may impart tensile in the pellicle membrane 310, and thus the pellicle membrane 310 may be stretched. However, when the pellicle border 308 keep moving upwards, the pellicle membrane 310 may no longer bear the upward force from the pellicle border 308, and the pellicle membrane 310 may be ruptured. Accordingly, embodiments of the present disclosure provide a method of transferring a pellicle membrane on a pellicle border, and such method can not only maintain the mechanical strength of the pellicle membrane, but can also obtain a better transparency and an improved flatness of the pellicle membrane.

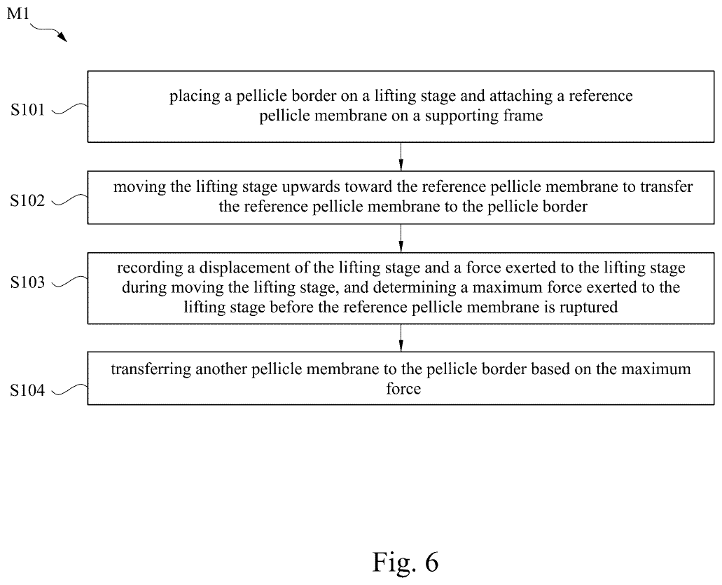

FIG. 6 is a method of operating a pellicle membrane transferring system in accordance with some embodiments. Shown there is a method M1. Although the method M1 is described as a series of acts, it will be appreciated that these acts are not limiting in that the order of the acts can be altered in other embodiments. In other embodiments, some acts that are illustrated and/or described may be omitted in whole or in part.

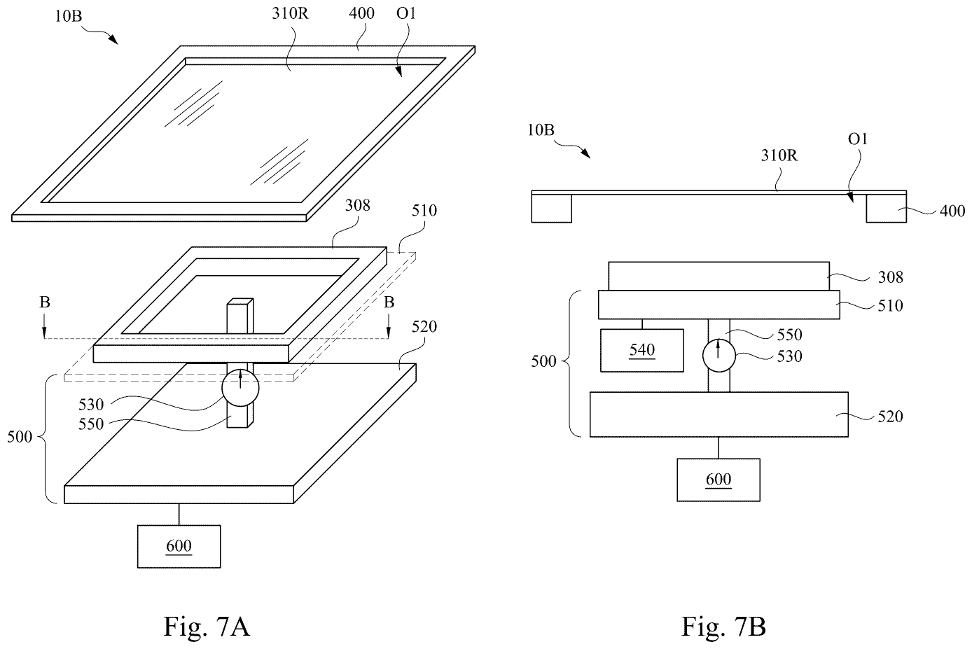

The method M1 starts from operation S101, by placing a pellicle border on a lifting stage and attaching a reference pellicle membrane on a supporting frame. As shown in FIGS. 7A and 7B, in which FIG. 7B is a cross-sectional view along line B-B of FIG. 7A. Shown there is a pellicle membrane transferring system 10B. A pellicle border 308 is disposed on a lifting stage 500. On the other hand, a reference pellicle membrane 310R is attached to a supporting frame 400. In some embodiments, the reference pellicle membrane 310R may be the same or similar to the pellicle membrane 310 as discussed above.

In greater detail, the lifting stage 500 may include a top platform 510, a bottom platform 520, and a force sensor 530 between the top platform 510 and the bottom platform 520. In some embodiments, the force sensor 530 is disposed on a pillar structure 550 between the top platform 510 and the bottom platform 520. The lifting stage 500 may include a stepper motor. In some embodiments, the stepper motor is disposed in the bottom platform 520, and the stepper motor is able to lift the bottom platform 520, so as to push the force sensor 530 and the top platform 510 upwards. In other embodiments, the bottom platform 520 is fixed, and the stepper motor is disposed in the pillar structure 550. The stepper motor in the pillar structure 550 is able to lift the pillar structure 550 (e.g., the pillar structure 550 may extend vertically), so as to push the top platform 510 upwards. In the embodiments of FIGS. 7A and 7B, shown there is a single the force sensor 530, while in other embodiments more force sensors may also be applied.

The lifting stage 500 further includes a displacement measuring device 540, and the displacement measuring device 540 can detect the displacement of the top platform 510. It is noted that because the pellicle border 308 is moved along with the top platform 510, and thus the displacement of the top platform 510 is the same as the displacement of the pellicle border 308. In some embodiments, the displacement measuring device 540 can be linear variable differential transformer (LVDT), a string potentiometer, a laser distance Sensor, an ultrasonic sensor, a magnetostrictive sensor, an inductive displacement Sensor, or other suitable sensor.

In some embodiments, an alignment process may be performed to align the pellicle border 308 with the supporting frame 400. The alignment process may include, for example, moving the pellicle border 308 horizontally until the center of the pellicle border 308 is vertically aligned with the center of the supporting frame 400. In some embodiments, the force sensor 530 as well as the pillar structure 550 may also be vertically aligned with the center of the opening of the pellicle border 308.

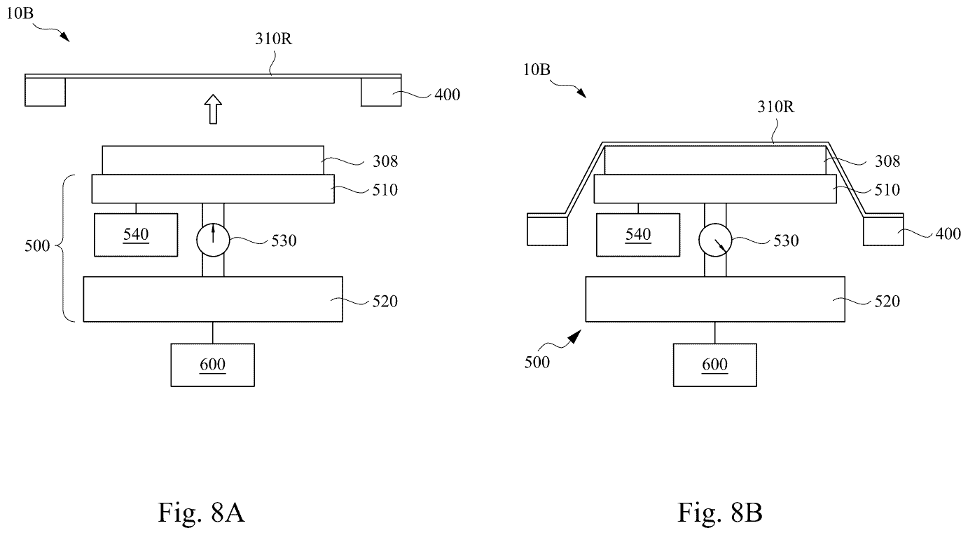

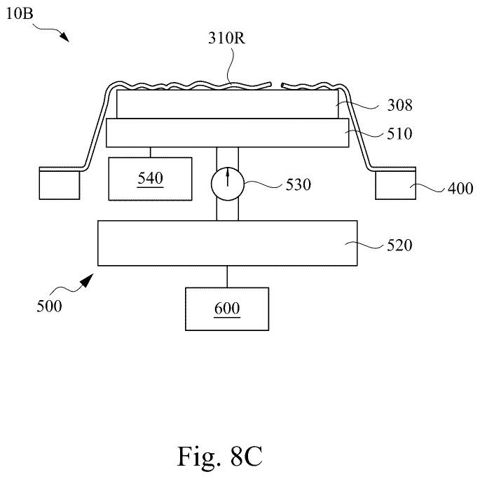

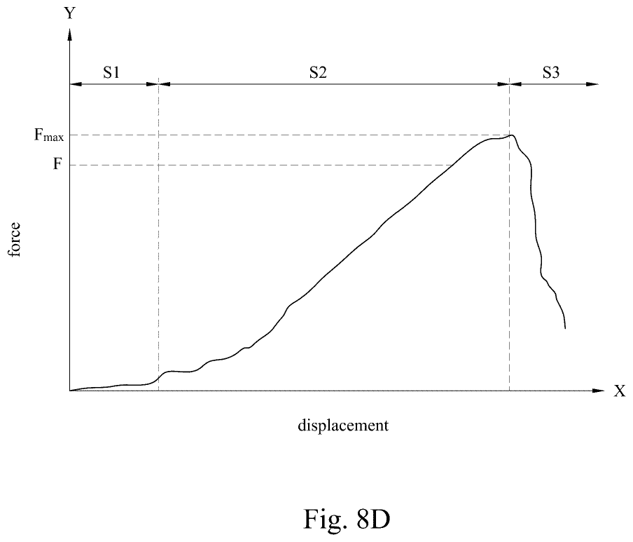

The method M1 proceeds to operation S102, by moving the lifting stage upwards toward the reference pellicle membrane to transfer the reference pellicle membrane to the pellicle border. Reference is made to FIGS. 8A, 8B, and 8C. In FIG. 8A, the pellicle border 308 is moved upwards, through the lifting stage 500, toward the reference pellicle membrane 310R. In FIG. 8B, during the vertical movement of the pellicle border 308, the pellicle border 308 starts to contact the reference pellicle membrane 310R, pushes the reference pellicle membrane 310R, and imparts tensile in the reference pellicle membrane 310R. In FIG. 8C, when the pellicle border 308 continuously moves upwards, the reference pellicle membrane 310R may no longer bear the upward force from the pellicle border 308, and thus the reference pellicle membrane 310R will be ruptured.

The method M1 proceeds to operation S103, by recording a displacement of the lifting stage and a force exerted on the lifting stage during moving the lifting stage, and determining a maximum force exerted on the lifting stage before the reference pellicle membrane is ruptured. During the vertical movement of the pellicle border 308, the displacement of the lifting stage 500 and the force exerted on the lifting stage 500 are recorded. In greater detail, the displacement of the top platform 510 of the lifting stage 500 and the force exerted on the top platform 510 of the lifting stage 500 are recorded. For example, the displacement measuring device 540 can record the displacement of the top platform 510 of the lifting stage 500, and the force sensor 530 can record the force exerted on the top platform 510.

Here, the displacement of the top platform 510 of the lifting stage 500 may be the same as the displacement of the pellicle border 308. Accordingly, the displacement of the top platform 510 of the lifting stage 500 discussed herein can also be interchanged with the displacement of the pellicle border 308. On the other hand, during transferring the reference pellicle membrane 310R to the pellicle border 308, the pellicle border 308 and the reference pellicle membrane 310R will exert forces upon each other. Moreover, because the pellicle border 308 is made of a rigid material, the force may also be transferred to the top platform 510 of the lifting stage 500. Accordingly, the force exerted on the top platform 510 of the lifting stage 500 may be substantially the same as the force exerted on pellicle border 308, and may also be the same as the force exerted on the reference pellicle membrane 310R. Accordingly, the force exerted on the top platform 510 of the lifting stage 500 can also be interchanged with the force exerted on pellicle border 308 or the force applied to the reference pellicle membrane 310R.

FIG. 8D is a displacement versus force plot in accordance with some embodiments of the present disclosure. In FIG. 8D, the horizontal axis may be the displacement of the top platform 510 of the lifting stage 500, and the vertical axis may be the force exerted on the top platform 510 of the lifting stage 500. Shown there is a curve, in which the curve includes a first segment S1, a second segment S2, and a third segment S3.

With respect to the first segment S1, the first segment S1 may correspond to the condition as shown in FIG. 8A where the pellicle border 308 is moved upwards but does not contact the reference pellicle membrane 310R. Accordingly, when the displacement of the top platform 510 of the lifting stage 500 increases, the force detected by the force sensor 530 is about zero or negligibly small.

With respect to the second segment S2, the second segment S2 may correspond to the condition as shown in FIG. 8B where the pellicle border 308 starts to contact the reference pellicle membrane 310R. Accordingly, when the displacement of the pellicle border 308 increases, the force detected by the force sensor 530 may also increase. This is because when the pellicle border 308 pushes the reference pellicle membrane 310R, the reference pellicle membrane 310R will be tightened, and thus the top platform 510 of the lifting stage 500 will bear a larger force when the displacement of the top platform 510 of the lifting stage 500 increases. In some embodiments, in the second segment S2, the curve may include a linear region where the force is proportional to the displacement. In other embodiments, the second segment S2 may not be a linear region.

With respect to the third segment S3, the third segment S3 may correspond to the condition as shown in FIG. 8C where the reference pellicle membrane 310R is ruptured. In the second segment S2, the detected force may increase to a maximum force Fₘₐₓ. Once the reference pellicle membrane 310R is ruptured, the detected force may suddenly drop off. This is because the pellicle border 308 no longer bears the stress from the tightened reference pellicle membrane 310R.

In some embodiments, the maximum force Fₘₐₓ may also be referred to as the “ultimate strength” of the reference pellicle membrane 310R in the pellicle membrane transferring system 10B. Here, the term “ultimate strength” may be a maximum force that a material (e.g., the reference pellicle membrane 310R) can withstand before it breaks or weakens. It is noted that the absolute value of the maximum force Fₘₐₓ is not important, the maximum force Fₘₐₓ can be used as a reference in the following process. In some embodiments, the maximum force Fₘₐₓ can be recorded by a control system 600.

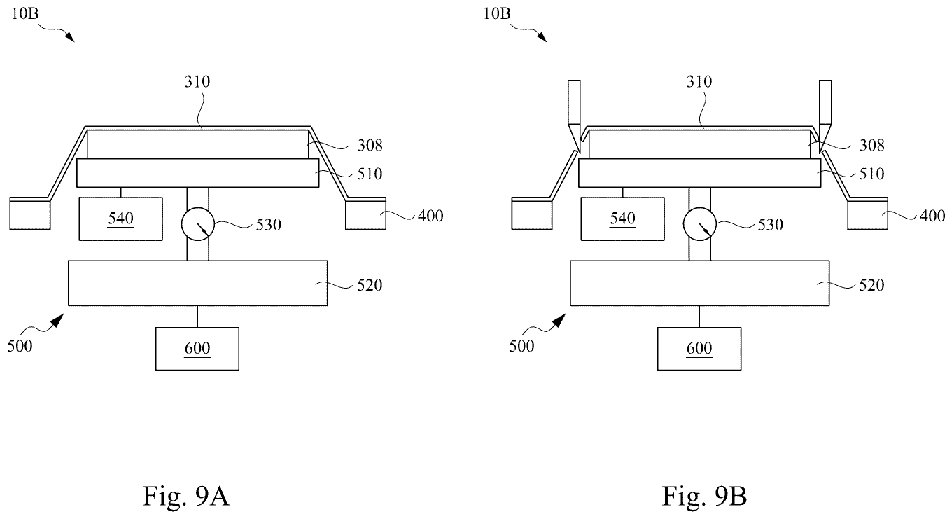

The method M1 proceeds to operation S104, by transferring another pellicle membrane to the pellicle border based on the maximum force. As shown in FIG. 9A, a new pellicle membrane 310 is attached on the supporting frame 400, and the pellicle border 308 is placed on the stage 500. It is noted that the pellicle border 308 can also be a new pellicle border, and is not necessary to be the original pellicle border 308 used in the steps S101 to S103. The new pellicle membrane 310 may be the same or similar to the reference pellicle membrane 310R as discussed above, and thus new pellicle membrane 310 may include the same mechanical property as the reference pellicle membrane 310R (e.g., the curve C1 of FIG. 8D).

Once the pellicle border 308 is properly aligned with the supporting frame 400, the pellicle border 308 is moved upwards toward the pellicle membrane 310 and pushes the pellicle membrane 310. During the movement of the pellicle border 308, the force sensor 530 may continuously detect the force exerted on the top platform 510 of the lifting stage 500.

In some embodiments, the movement of the pellicle border 308 is stopped once the detected force reaches the maximum force. That is, when the detected force reaches the maximum force Fₘₐₓ in FIG. 8D, the lifting stage 500 may stop moving the pellicle border 308.

In other embodiments, the movement of the pellicle border 308 is stopped once the detected force is slightly less than the ultimate strength. For example, as shown in FIG. 8D, when the detected force reaches a force F that is less than the maximum force Fₘₐₓ, the lifting stage 500 may stop moving the pellicle border 308. In some embodiments, the force F may satisfy 0.5 Fₘₐₓ<F<0.9 Fₘₐₓ. In other embodiments, the force F may satisfy 0.6 Fₘₐₓ<F<0.9 Fₘₐₓ. In some embodiments, the lower boundary of the force F may be about 0.5 Fₘₐₓ, 0.6 Fₘₐₓ, 0.7 Fₘₐₓ, or 0.8 Fₘₐₓ, and the upper boundary of the force F may be about 0.8 Fₘₐₓ, 0.9 Fₘₐₓ, or 0.95 Fₘₐₓ.

In some embodiments, the pellicle membrane transferring system 10B also includes a control system 600 electrically coupled to the lifting stage 500. In some embodiments, the control system 600 may include a controller and a computer readable storage medium encoded with, i.e., storing, a computer program code, i.e., a set of executable instructions. The controller is electrically coupled to the computer readable storage medium. The controller is configured to execute the computer program code encoded in the computer readable storage medium in order to cause the control system 600 to be used to perform the operations as discussed above with respect to FIG. 6.

In some embodiments, the controller is a central processing unit (CPU), a multi-processor, a distributed processing system, an application specific integrated circuit (ASIC), and/or a suitable processing unit. In some embodiments, the computer readable storage medium includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium includes a compact disk-read only memory (CD-ROM), a compact disk-read/write (CD-R/W), and/or a digital video disc (DVD). In some embodiments, the controller may include artificial intelligence (AI) function. For example, the data collected during the operation can be used to train the AI learning the optimized parameter.

In some embodiments, the operation S104 may be performed several times. For example, once a pellicle membrane 310 is worn out after performing several lithography processes, the pellicle membrane 310 can be replaced with a new pellicle membrane 310. In some embodiments, a first pellicle membrane 310 may be transferred to a pellicle border 308 to form a pellicle structure (e.g., the pellicle structure 300 in FIGS. 3A and 3B). Several lithography processes can be performed using the pellicle structure having the first pellicle membrane 310. Once the first pellicle membrane 310 is worn out after performing several lithography processes, the first pellicle membrane 310 can be replaced with a second pellicle membrane 310. The first pellicle membrane 310 is removed from the pellicle border 308, and the second pellicle membrane 310 is transferred to the pellicle border 308. In other cases, the pellicle membrane 310 may be modified by certain processes, such as coating a protective layer on the pellicle membrane 310. This could cause the membrane to sag, necessitating it to be tightened. In such cases, the sagging membrane can be tightened using this pellicle transferring system. The protective layer can be coated on the membrane with a larger border, and then transfer it to a smaller border (the pellicle size utilized in the EUV lithography process) after the coating process.

It is understood that during transferring the first pellicle membrane 310 and the second pellicle membrane 310 to the pellicle border 308, the force sensor 530 will record the force exerted on the top platform 510 as discussed above. In some embodiments, the transferring conditions of transferring the first pellicle membrane 310 and transferring the second pellicle membrane 310 are substantially the same. For example, during transferring the first pellicle membrane 310, the movement of the lifting stage 500 may be stopped once the detected force by the force sensor 530 reaches a pre-determined value. Similarly, during transferring the second pellicle membrane 310, the movement of the lifting stage 500 may be stopped once the detected force by the force sensor 530 reaches the same pre-determined value. Such configuration may ensure a uniform transferring quality, and will improve the consistency of lithography processes.

Reference is made to FIG. 9B. Once the pellicle border 308 is moved to a desired position, the pellicle membrane 310 is cut out. Afterwards, the pellicle border 308 and the pellicle membrane 310 attached to the pellicle border 308 can be removed from the lifting stage 500. Then, the pellicle border 308 can be mounted on a pellicle frame 302 through a pellicle frame adhesive 306 (see FIGS. 3A and 3B), and thus the pellicle structure 300 as discussed in FIGS. 3A and 3B is formed.

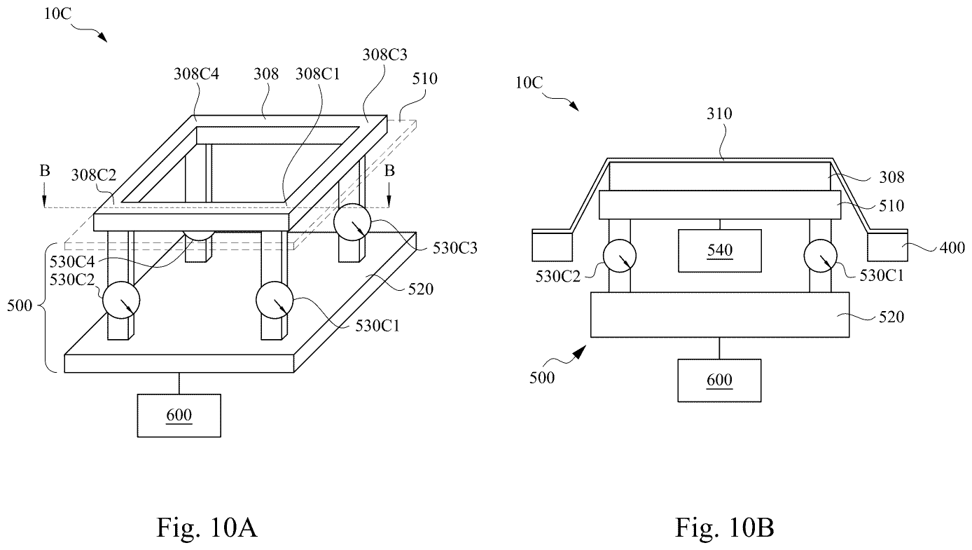

FIGS. 10A and 10B are a schematic view and a cross-sectional view of a pellicle membrane transferring system in accordance with some embodiments. Shown there is a pellicle membrane transferring system 10C. It is noted that the pellicle membrane transferring system 10C of FIGS. 10A and 10B may be similar to the pellicle membrane transferring systems as discussed above, similar elements will be labeled the same, and relevant details will not be repeated for brevity.

In FIGS. 10A and 10B, the lifting stage 500 includes four force sensors 530C1, 530C2, 530C3, and 530C4. In some embodiments, when the pellicle border 308 is disposed on the top platform 510 of the lifting stage 500, the force sensors 530C1, 530C2, 530C3, and 530C4 may be vertically below the corners 308C1, 308C2, 308C3, and 308C4 of the pellicle border 308.

The pellicle membrane transferring system 10C can also be used in the method M1 as discussed in FIG. 6. For example, the pellicle border 308 is moved upwards toward a reference pellicle membrane, pushing the reference pellicle membrane, until the reference pellicle membrane is ruptured. In some embodiments, the force sensors 530C1, 530C2, 530C3, and 530C4 can detect forces during the vertical movement of the top platform 510. Moreover, the control system 600 may control the lifting stage 500, such that the detected forces of the force sensors 530C1, 530C2, 530C3, and 530C4 are substantially the same. For example, after the pellicle border 308 contacts the reference pellicle membrane 310R, the detected forces of the force sensors 530C1, 530C2, 530C3, and 530C4 starts to increase. In some embodiments, if the detected force of the force sensor 530C1 is less than the detected forces of the force sensors 530C2, 530C3, and 530C4, the control system 600 may control the lifting stage 500, such that the lifting stage 500 may increase the upward force to the corner 308C1 of the pellicle border 308. As a result, once the reference pellicle membrane 310R is ruptured, the displacement versus force plots obtained from the force sensors 530C1, 530C2, 530C3, and 530C4 and the displacement measurement device 540 may be substantially the same. That is, the maximum force (e.g., the maximum force Fₘₐₓ in FIG. 8D) obtained from the force sensors 530C1, 530C2, 530C3, and 530C4 may be substantially the same.

Accordingly, during transferring a new pellicle membrane 310 to the pellicle border 308, the pellicle border 308 is moved upwards toward the pellicle membrane 310 and pushes the pellicle membrane 310. During the movement of the top platform 510, the force sensors 530C1, 530C2, 530C3, and 530C4 may continuously detect the forces. Moreover, the control system 600 may control the lifting stage 500, such that the detected forces of the force sensors 530C1, 530C2, 530C3, and 530C4 are substantially the same. In some embodiments, the movement of the top platform 510 is stopped once one of the detected forces of the force sensors 530C1, 530C2, 530C3, and 530C4 reaches the maximum force (e.g., the maximum force Fₘₐₓ in FIG. 8D). In other embodiments, the movement of the top platform 510 is stopped once one of the detected forces of the force sensors 530C1, 530C2, 530C3, and 530C4 is slightly less than the maximum force (e.g., the maximum force Fₘₐₓ in FIG. 8D).

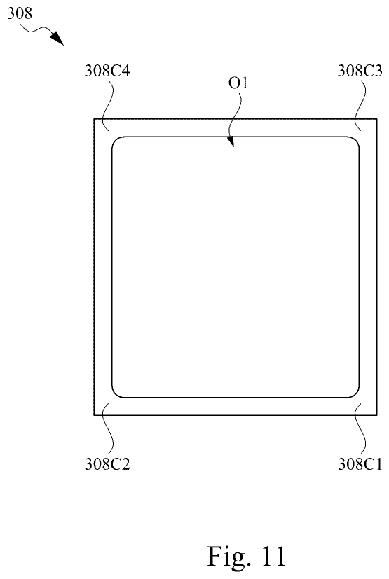

FIG. 11 is a top view of a pellicle border in accordance with some embodiments. Shown there is a pellicle border 308, in which the pellicle border 308 can be used in the pellicle membrane transferring system 10C of FIGS. 10A and 10B or other pellicle membrane transferring systems in the present disclosure. As shown in FIGS. 10A and 10B, because the force sensors 530C1, 530C2, 530C3, and 530C4 of the pellicle membrane transferring system 10C of FIGS. 10A and 10B are disposed under the corners 308C1, 308C2, 308C3, and 308C4 of the pellicle border 308, the corners 308C1, 308C2, 308C3, and 308C4 may bear larger forces when the lifting stage 500 pushes the pellicle border 308. In FIG. 11, the opening O1 of the pellicle border 308 (or inner boundary of the pellicle border 308) has a rounded rectangle top profile, while the outer boundary of the pellicle border 308 has a right rectangle top profile. Stated another way, the opening O1 of the pellicle border 308 (or inner boundary of the pellicle border 308) has rounded corners, while the outer boundary of the pellicle border 308 has corners with right angle. Such configuration may increase the thickness of the pellicle border 308 at the corners 308C1, 308C2, 308C3, and 308C4, and will improve the mechanical strength of the pellicle border 308. In other embodiments, the outer boundary of the pellicle border 308 may also include rounded corners.

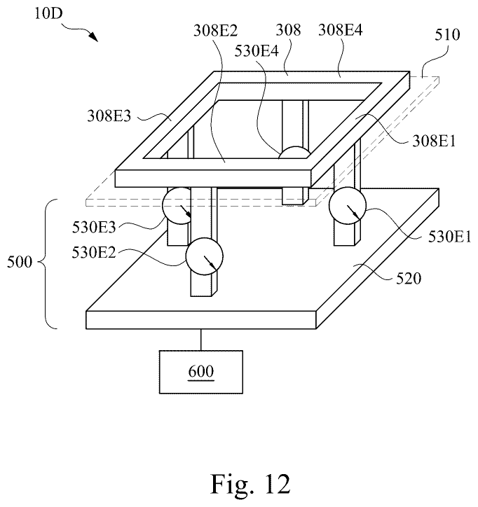

FIG. 12 is a schematic view of a pellicle membrane transferring system in accordance with some embodiments. Shown there is a pellicle membrane transferring system 10D. It is noted that the pellicle membrane transferring system 10D of FIG. 12 may be similar to the pellicle membrane transferring systems as discussed above, similar elements will be labeled the same, and relevant details will not be repeated for brevity. It is noted that, although not illustrated in FIG. 12, the pellicle membrane transferring system 10D may also include the displacement measuring device 540 as discussed above.

In FIG. 12, the lifting stage 500 includes four force sensors 530E1, 530E2, 530E3, and 530E4. In some embodiments, when the pellicle border 308 is disposed on the top platform 510 of the lifting stage 500, the force sensors 530E1, 530E2, 530E3, and 530E4 may be vertically below the edges 308E1, 308E2, 308E3, and 308E4 of the pellicle border 308.

The pellicle membrane transferring system 10D can also be used in the method M1 as discussed in FIG. 6. For example, the pellicle border 308 is moved upwards toward a reference pellicle membrane, pushing the reference pellicle membrane, until the reference pellicle membrane is ruptured. In some embodiments, the force sensors 530E1, 530E2, 530E3, and 530E4 can detect forces during the vertical movement of the top platform 510. Moreover, the control system 600 may control the lifting stage 500, such that the detected forces of the force sensors 530E1, 530E2, 530E3, and 530E4 are substantially the same. For example, after the pellicle border 308 contacts the reference pellicle membrane 310R, the detected forces of the force sensors 530E1, 530E2, 530E3, and 530E4 starts to increase. In some embodiments, if the detected force of the force sensor 530E1 is less than the detected forces of the force sensors 530E2, 530E3, and 530E4, the control system 600 may control the lifting stage 500, such that the lifting stage 500 may increase the upward force to the edge 308E1 of the pellicle border 308. As a result, once the reference pellicle membrane 310R is ruptured, the displacement versus force plots generated from the force sensors 530E1, 530E2, 530E3, and 530E4 may be substantially the same. That is, the maximum force (e.g., the maximum force Fₘₐₓ in FIG. 8D) obtained from the force sensors 530E1, 530E2, 530E3, and 530E4 may be substantially the same.

Accordingly, during transferring a new pellicle membrane 310 to the pellicle border 308, the pellicle border 308 is moved upwards toward the pellicle membrane 310 and pushes the pellicle membrane 310. During the movement of the top platform 510, the force sensors 530E1, 530E2, 530E3, and 530E4 may continuously detect the forces. Moreover, the control system 600 may control the lifting stage 500, such that the detected forces of the force sensors 530E1, 530E2, 530E3, and 530E4 are substantially the same. In some embodiments, the movement of the pellicle border 308 is stopped once one of the detected forces of the force sensors 530E1, 530E2, 530E3, and 530E4 reaches the maximum force (e.g., the maximum force Fₘₐₓ in FIG. 8D). In other embodiments, the movement of the pellicle border 308 is stopped once one of the detected forces of the force sensors 530E1, 530E2, 530E3, and 530E4 is slightly less than the maximum force (e.g., the maximum force Fₘₐₓ in FIG. 8D).

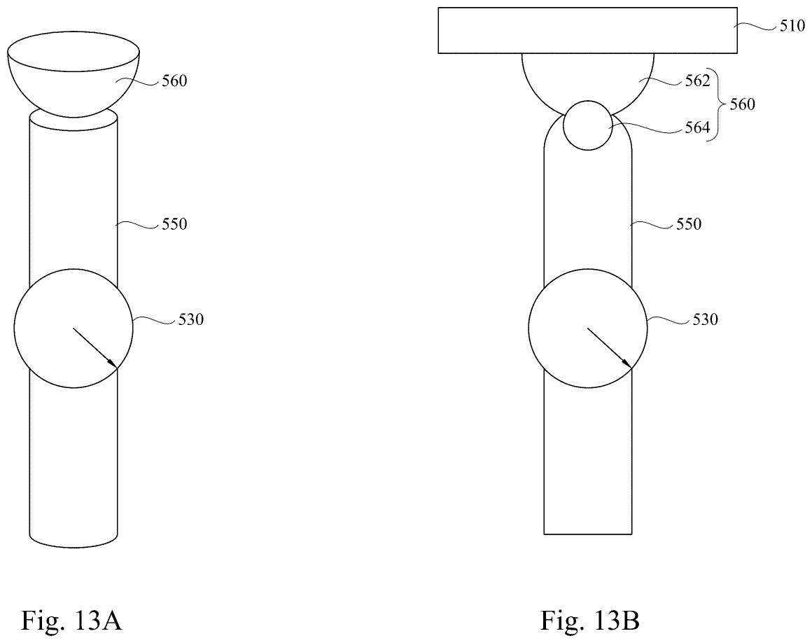

FIGS. 13A and 13B are a schematic view and a cross-sectional view of a pellicle membrane transferring system in accordance with some embodiments. As mentioned above, the force sensor 530 is disposed on a pillar structure 550. In some embodiments, a ball joint supporting structure 560 is coupled to the pillar structure 550, in which the ball joint supporting structure 560 can rotate in different orientations with respect to the pillar structure 550. As shown in FIG. 13B, the ball joint supporting structure 560 includes a supporting plate 562 and a ball joint 564 coupled with each other. In some embodiments, the supporting plate 562 may include a hemisphere shape, which includes a substantially flat top surface facing upwards and in contact with bottom surface of the top platform 510 of the lifting stage 500. On the other hand, the ball joint 564 has a ball structure engaged with a recess of the pillar structure 550. Such configuration can ensure a fixed contact area between the supporting plate 562 and the top platform 510, and is beneficial to apply a uniform upward force to the top platform 510. It is noted that the structure shown in FIGS. 13A and 13B can be applied in all pellicle membrane transferring system in the embodiments of the present disclosure. The concept of using the ball-joint supporting structure is to minimize the use of stepper motors required to adjust the lifting distance, as mentioned in FIGS. 10C, 10D, and 10E. The ball-joint support structure is designed to adjust the horizontal alignment of control system 600 and to equalize the forces exerted on all force sensors.

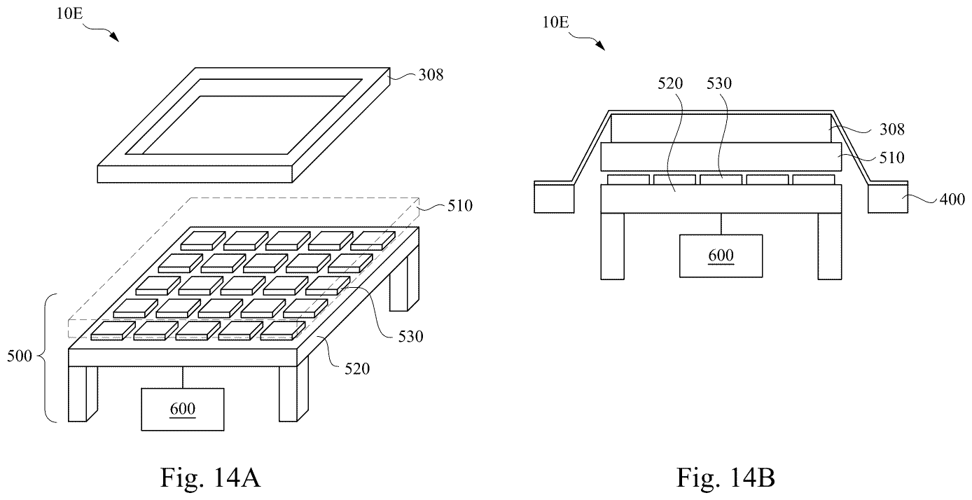

FIGS. 14A and 14B are a schematic view and a cross-sectional view of a pellicle membrane transferring system in accordance with some embodiments. Shown there is a pellicle membrane transferring system 10E. It is noted that the pellicle membrane transferring system of FIGS. 14A and 14B may be similar to the pellicle membrane transferring systems as discussed above, similar elements will be labeled the same, and relevant details will not be repeated for brevity. It is noted that, although not illustrated in FIGS. 14A and 14B, the pellicle membrane transferring system 10E may also include the displacement measuring device 540 as discussed above.

The pellicle membrane transferring system 10E includes a plurality of force sensors 530 disposed between the top platform 510 and the bottom platform 520 of the lifting stage 500, in which the force sensors 530 are arranged in a matrix. In the depicted embodiments, the force sensors 530 are arranged in a 5×5 matrix, while the disclosure is not limited thereto. For example, the force sensors 530 may be arranged in an N×N matrix, in which N is greater than 2. In some embodiments, once the pellicle border 308 is disposed on the top platform 510, the frame of the pellicle border 308 may vertically overlap portions of the force sensors 530, and the opening of the pellicle border 308 may vertically overlap other portions of the force sensors 530. In some embodiments, the force sensors 530 may also be disposed on a pillar structure as discussed above, and thus relevant details will not be repeated for brevity.

In some embodiments, each of the force sensors 530 may also include an individual stepper motor. Accordingly, by adjusting each stepper motor, the force detected from the force sensors 530 at different positions can be controlled as close as possible, which will improve the pellicle transferring performance.

According to the aforementioned embodiments, it can be seen that the present disclosure offers advantages in fabricating integrated circuits. It is understood, however, that other embodiments may offer additional advantages, and not all advantages are necessarily disclosed herein, and that no particular advantage is required for all embodiments. Embodiments of the present disclosure provide a method by detecting a maximum force that a reference pellicle membrane can withstand before it is ruptured. Accordingly, once a new pellicle membrane is transferred to a pellicle border, the movement of the pellicle border can be stopped until the detected force from the force sensor reaches the maximum force. With such configuration, the pellicle membrane may include a better transparency without under the risk of rupture. Accordingly, the transferring yield and the lithography performance can be improved.

In some embodiments of the present disclosure, a method includes placing a pellicle border on a lifting stage, wherein the lifting stage comprises at least one force sensor; lifting the lifting stage to move the pellicle border toward to contact a pellicle membrane, wherein during lifting the lifting stage, the at least one force sensor in the lifting stage detects a force exerted on the lifting stage; and stopping moving the pellicle border once the force detected by the at least one force sensor reaches a predetermined value.

In some embodiments, the at least one force sensor is vertically aligned with a center the pellicle border.

In some embodiments, the lifting stage comprises a plurality of force sensors.

In some embodiments, moving the pellicle border toward the pellicle membrane is controlled such that forces detected by the plurality of force sensors are substantially the same.

In some embodiments, the plurality of force sensors are vertically aligned with respective corners of the pellicle border during moving the pellicle border.

In some embodiments, the plurality of force sensors are vertically aligned with respective edges of the pellicle border during moving the pellicle border.

In some embodiments, the plurality of force sensors are arranged in a matrix.

In some embodiments, portions of the plurality of force sensors are vertically aligned with a frame of the pellicle border, and other portions of the plurality of force sensors are vertically aligned with an opening of the pellicle border.

In some embodiments of the present disclosure, a method includes moving, using a lifting stage, a pellicle border toward to contact a reference pellicle membrane until the reference pellicle membrane is ruptured; detecting a first force exerted on the lifting stage during moving the pellicle border through a force sensor in the lifting stage; recording a maximum force detected by the force sensor before the reference pellicle membrane is ruptured; and transferring a new pellicle membrane to the pellicle border based on the maximum force.

In some embodiments, transferring the new pellicle membrane to the pellicle border based on the maximum force comprises moving the pellicle border toward to contact the new pellicle membrane, wherein during moving the pellicle border, the force sensor in the lifting stage detects a second force exerted on the lifting stage; and stopping moving the pellicle border once the second force detected by the force sensor reaches the maximum force.

In some embodiments, transferring the new pellicle membrane to the pellicle border based on the maximum force comprises moving the pellicle border toward to contact the new pellicle membrane, wherein during moving the pellicle border, the force sensor in the lifting stage detects a second force exerted on the lifting stage; and stopping moving the pellicle border once the second force and the maximum force satisfy 0.5 Fₘₐₓ<F<0.9 Fₘₐₓ, wherein Fₘₐₓ is the maximum force, and F is the second force.

In some embodiments, transferring the new pellicle membrane to the pellicle border based on the maximum force comprises moving the pellicle border toward to contact the new pellicle membrane, wherein during moving the pellicle border, the force sensor in the lifting stage detects a second force exerted on the lifting stage; and stopping moving the pellicle border once the second force and the maximum force satisfy 0.6 Fₘₐₓ<F<0.9 Fₘₐₓ, wherein Fₘₐₓ is the maximum force, and F is the second force.

In some embodiments, the lifting stage comprises a platform and a pillar structure supporting the platform, wherein the force sensor is disposed on the pillar structure.

In some embodiments, the pillar structure supports the platform through a supporting structure, and the supporting structure is coupled with the pillar structure via ball joint.

In some embodiments of the present disclosure, a pellicle membrane transferring system includes a supporting frame configured to support a pellicle membrane. A lifting stage is configured to move a pellicle border toward to contact the pellicle membrane. The lifting stage comprises a platform configured to support the pellicle border, and at least one force sensor below the platform and configured to detect a force exerted on the platform during the pellicle border contacts the pellicle membrane.

In some embodiments, the lifting stage comprises one force sensor, and the force sensor is vertically aligned with a center of the pellicle border.

In some embodiments, the lifting stage comprises a plurality of force sensors vertically aligned with respective corners of the pellicle border.

In some embodiments, the lifting stage comprises a plurality of force sensors vertically aligned with respective edges of the pellicle border.

In some embodiments, the lifting stage comprises a plurality of force sensors arranged in a matrix.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
placing a pellicle border on a lifting stage, wherein the lifting stage comprises at least one force sensor;
lifting the lifting stage to move the pellicle border toward to contact a pellicle membrane, wherein during lifting the lifting stage, the at least one force sensor in the lifting stage detects a force exerted on the lifting stage; and
stopping moving the pellicle border once the force detected by the at least one force sensor reaches a predetermined value.

2. The method of claim 1, further comprising:
prior to placing the pellicle border on the lifting stage, lifting the lifting stage to move the pellicle border toward to contact a reference pellicle membrane until the reference pellicle membrane is ruptured, wherein the at least one force sensor in the lifting stage records a maximum force before the reference pellicle membrane is ruptured, and wherein the predetermined value is less than the maximum force; and
removing the reference pellicle membrane from the pellicle border.

3. The method of claim 1, wherein the at least one force sensor is vertically aligned with a center the pellicle border.

4. The method of claim 1, wherein the lifting stage comprises a plurality of force sensors.

5. The method of claim 4, wherein moving the pellicle border toward the pellicle membrane is controlled such that forces detected by the plurality of force sensors are substantially the same.

6. The method of claim 4, wherein the plurality of force sensors are vertically aligned with respective corners of the pellicle border during moving the pellicle border.

7. The method of claim 4, wherein the plurality of force sensors are vertically aligned with respective edges of the pellicle border during moving the pellicle border.

8. The method of claim 4, wherein the plurality of force sensors are arranged in a matrix.

9. The method of claim 8, wherein portions of the plurality of force sensors are vertically aligned with a frame of the pellicle border, and other portions of the plurality of force sensors are vertically aligned with an opening of the pellicle border.

10. A method, comprising:
moving, using a lifting stage, a pellicle border toward to contact a reference pellicle membrane until the reference pellicle membrane is ruptured;
detecting a first force exerted on the lifting stage during moving the pellicle border through a force sensor in the lifting stage;
recording a maximum force detected by the force sensor before the reference pellicle membrane is ruptured; and
transferring a new pellicle membrane to the pellicle border based on the maximum force.

11. The method of claim 10, wherein transferring the new pellicle membrane to the pellicle border based on the maximum force comprises:
moving the pellicle border toward to contact the new pellicle membrane, wherein during moving the pellicle border, the force sensor in the lifting stage detects a second force exerted on the lifting stage; and
stopping moving the pellicle border once the second force detected by the force sensor reaches the maximum force.

12. The method of claim 10, wherein transferring the new pellicle membrane to the pellicle border based on the maximum force comprises:
moving the pellicle border toward to contact the new pellicle membrane, wherein during moving the pellicle border, the force sensor in the lifting stage detects a second force exerted on the lifting stage; and
stopping moving the pellicle border once the second force and the maximum force satisfy 0.5 Fₘₐₓ<F<0.9 Fₘₐₓ, wherein Fₘₐₓ is the maximum force, and F is the second force.

13. The method of claim 10, wherein transferring the new pellicle membrane to the pellicle border based on the maximum force comprises:
moving the pellicle border toward to contact the new pellicle membrane, wherein during moving the pellicle border, the force sensor in the lifting stage detects a second force exerted on the lifting stage; and
stopping moving the pellicle border once the second force and the maximum force satisfy 0.6 Fₘₐₓ<F<0.9 Fₘₐₓ, wherein Fₘₐₓ is the maximum force, and F is the second force.

14. The method of claim 10, wherein the lifting stage comprises:
a platform; and
a pillar structure supporting the platform, wherein the force sensor is disposed on the pillar structure.

15. The method of claim 14, wherein the pillar structure supports the platform through a supporting structure, and the supporting structure is coupled with the pillar structure via a ball joint.

16. A pellicle membrane transferring system, comprising:
a supporting frame configured to support a pellicle membrane; and
a lifting stage configured to move a pellicle border toward to contact the pellicle membrane, and wherein the lifting stage comprises:
a platform configured to support the pellicle border; and
at least one force sensor below the platform and configured to detect a force exerted on the platform during the pellicle border contacts the pellicle membrane.

17. The pellicle membrane transferring system of claim 16, wherein the lifting stage comprises one force sensor, and the force sensor is vertically aligned with a center of the pellicle border.

18. The pellicle membrane transferring system of claim 16, wherein the lifting stage comprises a plurality of force sensors vertically aligned with respective corners of the pellicle border.

19. The pellicle membrane transferring system of claim 16, wherein the lifting stage comprises a plurality of force sensors vertically aligned with respective edges of the pellicle border.

20. The pellicle membrane transferring system of claim 16, wherein the lifting stage comprises a plurality of force sensors arranged in a matrix.
